(19) United States
(12) Patent Application Publication
(10) Pub. No.: US 2025/0273597 A1
(43) Pub. Date: Aug. 28, 2025

(54) EMBEDDED SCAFFOLD STIFFENER IN SUBSTRATE

(71) Applicant: QUALCOMM Incorporated, San Diego, CA (US)

(72) Inventors: Omar James BCHIR, San Marcos, CA (US); David Fraser RAE, San Diego, CA (US); Jaewook SEOK, San Diego, CA (US); Jill Christine NOONAN, San Diego, CA (US); Kuiwon KANG, San Diego, CA (US); Joan Rey Villarba BUOT, Escondido, CA (US)

(21) Appl. No.: 18/589,192

(22) Filed: Feb. 27, 2024

(51) Int. Cl. H01L 23/00; H01L 21/48; H01L 21/683; H01L 23/498; H01L 23/552

(52) U.S. Cl. CPC H01L 23/562; H01L 21/4857; H01L 23/49838; H01L 23/552; H01L 21/6835; H01L 24/32; H01L 2221/68345; H01L 2224/32245

(57) ABSTRACT

In an aspect, an apparatus may include a package substrate including a metallization structure disposed in the package substrate. The metallization structure includes a plurality of conductive layers and a plurality of dielectric layers. The package substrate includes an embedded scaffold stiffener disposed on a perimeter of the metallization structure outside the metallization structure. The embedded scaffold stiffener includes a plurality of scaffold columns and a plurality of scaffold layers stacked vertically.

### TECHNICAL FIELD

The present disclosure generally relates to semiconductor devices including an integrated circuit (IC) package, and more particularly, but not exclusively, to devices including substrates with an embedded scaffold stiffener and fabrication techniques thereof.

### BACKGROUND

IC technology has achieved great strides in advancing computing power through miniaturization of electronic components. A semiconductor device generally referred to as an IC chip, an IC die, a chip or die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more dies into an IC package, which is different from the semiconductor substrate for forming a die.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like. As used herein the term “function block” should not be construed to be power or signal lines, traces, conductors, pads, etc. that merely function to transmit an electrical voltage and/or current.

As designs become more complex, package warpage control is critical to enable high yields during final integration into end devices, such as mounting/electrically coupling dies, package, interposers, surface mount technology (SMT) devices, SOC devices, motherboards/printed circuit boards (PCBs) and the like. Significant effort has been undertaken to change materials in the substrate, as well as mold compounds and use of external stiffeners/lids to control package warpage. As package footprints increase, and package thickness reduction continues, warpage control becomes more difficult.

Accordingly, there is a need for improved package substrates for semiconductor devices and methods of manufacturing the same to address the deficiencies in conventional designs, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

At least one aspect described herein includes an apparatus having a package substrate including: a metallization structure disposed in the package substrate, wherein the metallization structure includes a plurality of conductive layers and a plurality of dielectric layers; and an embedded scaffold stiffener disposed on a perimeter of the metallization structure outside the metallization structure, wherein the embedded scaffold stiffener includes a plurality of scaffold columns and a plurality of scaffold layers stacked vertically, each scaffold layer including: a metal layer; a plurality of stubs coupled to the metal layer; a dielectric layer disposed over the metal layer and the plurality of stubs; and a plurality of vias disposed through the dielectric layer and coupled to the plurality of stubs, wherein the plurality of scaffold columns include vertically aligned stubs and vias coupled to metal layers in each of the plurality of scaffold layers.

At least one aspect described herein includes a method of manufacturing an apparatus including: forming a metallization structure disposed in the package substrate, wherein the metallization structure includes a plurality of conductive layers and a plurality of dielectric layers; and forming an embedded scaffold stiffener disposed on a perimeter of the metallization structure outside the metallization structure, wherein the embedded scaffold stiffener includes a plurality of scaffold columns and a plurality of scaffold layers stacked vertically, each scaffold layer being formed by: forming a metal layer; forming a plurality of stubs coupled to the metal layer; depositing a dielectric layer over the metal layer and the plurality of stubs; and forming a plurality of vias disposed through the dielectric layer and coupled to the plurality of stubs, wherein the plurality of scaffold columns include vertically aligned stubs and vias coupled to metal layers in each of the plurality of scaffold layers.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B are partial cross-sectional views of an apparatus, according to aspects of the disclosure.

FIGS. 2A and 2B are partial cross-sectional views of an apparatus, according to aspects of the disclosure.

FIG. 3 is a partial cross-sectional view of an apparatus, according to aspects of the disclosure.

FIG. 4 is a partial cross-sectional view of an apparatus, according to aspects of the disclosure.

FIGS. 5A and 5B are partial cross-sectional views of an apparatus, according to aspects of the disclosure.

FIG. 6 is a partial cross-sectional view of an apparatus, according to aspects of the disclosure.

FIG. 7 is a partial cross-sectional view of an apparatus, according to aspects of the disclosure.

FIG. 8 is a partial cross-sectional view of an apparatus, according to aspects of the disclosure.

FIG. 9 is a partial plan view and partial cross-sectional view of an apparatus, according to aspects of the disclosure.

FIG. 10 is a partial plan view and partial cross-sectional view of an apparatus, according to aspects of the disclosure.

FIG. 11 is a partial plan view and partial cross-sectional views of an apparatus, according to aspects of the disclosure.

FIGS. 12A-12H illustrate structures at various stages of manufacturing/fabricating an apparatus, according to aspects of the disclosure.

FIG. 13 illustrates a method for manufacturing/fabricating and apparatus with a substrate with an embedded scaffold stiffener, according to aspects of the disclosure.

FIG. 14 illustrates a mobile device, according to aspects of the disclosure.

FIG. 15 illustrates various electronic devices that may incorporate a substrate with an embedded scaffold stiffener as disclosed herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, as used herein, terms such as about, approximately, generally, substantially in the range of, and the like indicate that the examples provided are not intended to be limited to the precise numerical values, geometric shapes, angles, etc. and include normal variations due to, manufacturing tolerances and variations, material variations, and other design considerations. Further, as used herein, terms such as top, bottom, above, below, first, last, front, back, adjacent, and the like indicate convenient indications of orientations, assemblies or arrangements of various elements in the examples provided and should not be construed as absolute orientations, assemblies or arrangements.

As noted in the foregoing, conventional designs don't adequately address warpage issues in substrates used in package substrates. The various aspects disclosed provide additional design options to control warpage, such as adding a stiffener inside the substrate (e.g., an embedded scaffold stiffener). In some aspects, the additional embedded scaffold stiffener may add to the IC package x-y footprint, if used as a ring on a perimeter of the metallization structure/package substrate, but the improvement to warpage may be sufficient to justify the increased area used. In some aspects, the embedded scaffold stiffener can also be grounded. In some aspects, the embedded scaffold stiffener can be used as part of a Faraday cage to reduce noise and improve isolation for sensitive circuitry passing through the package substrate. In some aspects, a metal lid or external stiffener can be used in combination with the embedded scaffold stiffener.

In the various aspects disclosed, to enhance design flexibility embedded scaffold stiffeners can be provided, which can reduce substrate warpage in comparison to conventional designs.

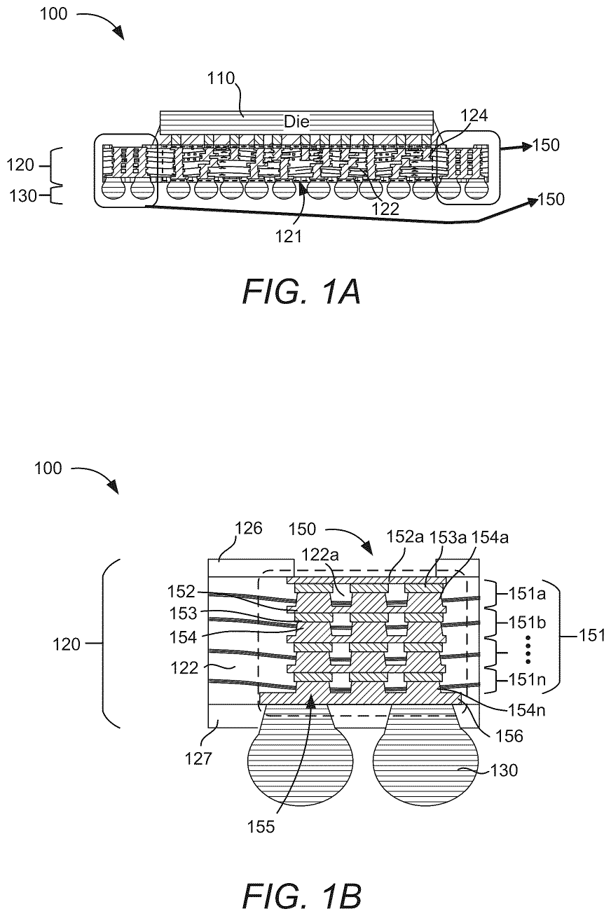

FIGS. 1A and 1B are partial cross-sectional views of an apparatus 100, according to aspects of the disclosure. In some aspects, FIGS. 1A and 1B are simplified partial cross-sectional views of the apparatus 100, and certain details and components of the apparatus 100 may be simplified or omitted in FIGS. 1A and 1B. In some aspects, the apparatus 100 may be a portion of an IC package and/or a larger apparatus such as a mobile phone, etc.

As shown in FIG. 1A, in some aspects, the apparatus 100 includes a die 110 disposed on a top surface of a package substrate 120, an embedded scaffold stiffener 150 and connectors 130 disposed on a bottom surface of the package substrate 120. In the various aspects disclosed, the embedded scaffold stiffener 150 is part of the package substrate 120. In some aspects, the package substrate 120 may include a metallization structure 121 disposed in the package substrate 120. The metallization structure may include a plurality of conductive layers 124 and a plurality of dielectric layers 122. In some aspects the metallization structure 121 may function at least in part as a redistribution layer (RDL) or otherwise provide connectivity from the die 110 to the connectors 130. In some aspects, the connectors 130 may be a ball grid array (BGA) comprising a plurality of solder balls, a land grid array (LGA) comprising a plurality of pins configured to interface to socket connectors on an external device (e.g., PCB), copper pillars, or any suitable electrical connector.

FIG. 1B illustrates a more detailed view of embedded scaffold stiffener 150. In some aspects, the embedded scaffold stiffener 150 includes a plurality of scaffold columns 155 and a plurality of scaffold layers 151 (e.g., 151a to 151n). The plurality of scaffold layers 151 are formed by a plurality of metal layers 152, a plurality of stubs 153 encapsulated in a plurality of dielectric layers 122 and a plurality of vias 154 disposed through the plurality of dielectric layers 122 and coupled to the plurality of stubs 153, as discussed herein. The plurality of scaffold columns 155 comprise vertically aligned stubs 153 and vias 154 coupled to metal layers 152 in each of the plurality of scaffold layers 151. A common label (e.g., dielectric layer 122) may be used to refer to an individual element or a plurality of elements, especially if the functionality of each are the same and/or the end assembly may be integrated into a common unit. Additionally, as used herein, elements with a subscript may indicate a specific element within a plurality of elements for convenience of reference. For example, the plurality of scaffold layers 151 includes a scaffold layer 151a comprising a metal layer 152a, a plurality of stubs 153a coupled to the metal layer 152a and the dielectric layer 122a disposed over the metal layer 152a and stubs 153a. The scaffold layer 151a also includes a plurality of vias 154a disposed through the dielectric layer 122a and coupled to the plurality of stubs 153a. Each of the plurality of vias 154a are coupled to a next metal layer of a next scaffold layer (e.g., metal layer 151b) of the plurality of scaffold layers 151a to 151n. Accordingly, the scaffold layers 151a to 151n of the embedded scaffold stiffener 150 can be designed for any number of layers and are sequentially coupled until a last scaffold layer 151n, where the plurality of vias 154n are coupled to a base metal layer 156 adjacent to the last scaffold layer 151n of the plurality of scaffold layers 151a to 151n.

The embedded scaffold stiffener 150 may be disposed on a perimeter of the metallization structure 121 (which may also be on a perimeter of the package substrate 120) outside the metallization structure 121, as illustrated. It will be appreciated that the perimeter of the metallization structure 121 defines a specific area within the package substrate 120 which may be related to one or more dies 110 and related components (if any), one or more functional blocks, or the entire package substrate. Further, for convenience of illustration, the perimeter of the package substrate 120 and/or the perimeter of the metallization structure 121 may be used in describing the location of the embedded scaffold stiffener 150, and may in many configurations may be substantially the same location. Further, it will be appreciated that the various aspects disclosed and claimed herein should not be interpreted to be limited to these specific examples.

In some aspects, at least a portion of a top or first metal layer (e.g., 151a) of the embedded scaffold stiffener 150 may be exposed through an opening in a first solder resist layer 126 to allow for coupling to other components, as discussed herein. In some aspects, the base metal layer 156 may be coupled to the connectors 130 through openings in a second solder resist layer 127 to allow for coupling to external components (e.g., PCB, additional package substrate, interposer, etc.) and/or to a ground potential, as discussed herein.

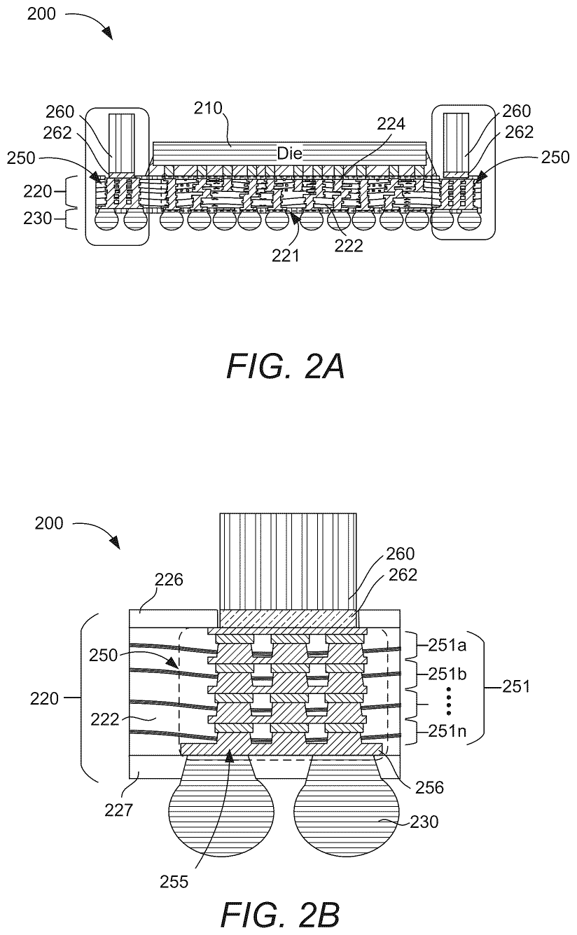

FIGS. 2A and 2B are partial cross-sectional views of an apparatus 200, according to aspects of the disclosure. In some aspects, FIGS. 2A and 2B are simplified partial cross-sectional views of the apparatus 200, and certain details and components of the apparatus 200 may be simplified or omitted in FIGS. 2A and 2B, particularly details that are similar to FIGS. 1A and 1B. In some aspects, the apparatus 200 may be a portion of an IC package and/or a larger apparatus such as a mobile phone, etc.

As shown in FIG. 2A, in some aspects, the apparatus 200 includes a die 210 coupled to a package substrate 220, an embedded scaffold stiffener 250, top external stiffener 260 and connectors 230. In the various aspects, the embedded scaffold stiffener 250 is part of the package substrate 220. In some aspects, the package substrate 220 may include a metallization structure 221 disposed in the package substrate 220. The metallization structure may include a plurality of conductive layers 224 including metal layers and vias and a plurality of dielectric layers 222. The embedded scaffold stiffener 250 may be disposed on a perimeter of the metallization structure 221 (which may also be on a perimeter of the package substrate 220) outside the metallization structure 221, as illustrated.

Further, a top external stiffener 260 may be disposed on top of the embedded scaffold stiffener 250 and coupled to the embedded scaffold stiffener 250 by a bonding layer 262. The top external stiffener 260 may be conductive or non-conductive. Likewise, the bonding layer 262 may be conductive or non-conductive. It will be appreciated that the top external stiffener 260 provides for further stiffening of the package substrate 220.

FIG. 2B illustrates a more detailed view of embedded scaffold stiffener 250 and top external stiffener 260. In some aspects, the embedded scaffold stiffener 250 includes a plurality of scaffold columns 255 and a plurality of scaffold layers 251, (e.g., 251a, 251b . . . 251n). As discussed above, each of the other scaffold layers includes a metal layer, a plurality of stubs coupled to the metal layer, a dielectric layer disposed over the metal layer and stubs, and vias interconnecting the stubs to subsequent metal layers. To avoid redundancy and clutter in the drawings, each of these elements may not be individually identified and/or illustrated. In some aspects, the same dielectric layers in the package substrate 220 are used in the embedded scaffold stiffener 250. In some aspects, the metallization structure 221 may be formed at the same time as the embedded scaffold stiffener 250 from the same materials. It will be appreciated that the scaffold layers 251a to 251n of the embedded scaffold stiffener 250 can be designed for any number of layers and are sequentially coupled until a last scaffold layer 251n of the plurality of scaffold layers 251a to 251n is coupled to a base metal layer 256 adjacent to the last scaffold layer 251n. Further, as illustrated, in some aspects, the bonding layer 262 couples the top external stiffener 260 to the embedded scaffold stiffener 250 at the top scaffold layer 251a. In some aspects the bonding layer 262 may be an adhesive, such as an epoxy or may be a conductive solder to facilitate grounding the top external stiffener 260. In some aspects the top external stiffener 260 may be a metal such as stainless steel. In some aspects, the top external stiffener 260 may be formed from a non-metal material, or another substrate, such as an interposer, a PCB or the like.

In some aspects, at least a portion of a top metal layer (e.g., 251a) of the top scaffold layer 251a may be exposed through an opening in a first solder resist layer 226 to allow for coupling to the top external stiffener 260 via bonding layer 262. In some aspects, the base metal layer 256 may be coupled to the connectors 230 through openings in a second solder resist layer 227 to allow for coupling to external components and/or to a ground potential, as discussed herein.

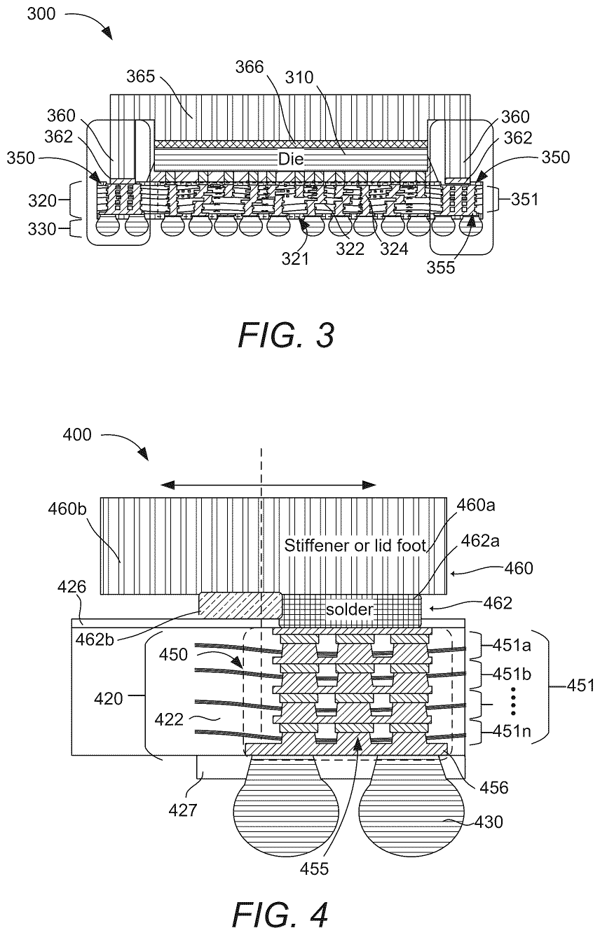

FIG. 3 is a partial cross-sectional view of an apparatus 300, according to aspects of the disclosure. In some aspects, FIG. 3 is a simplified partial cross-sectional view of the apparatus 300, and certain details and components of the apparatus 300 may be simplified or omitted in FIG. 3, particularly details that are similar to the foregoing FIGS. 1A through 2B. In some aspects, the apparatus 300 may be a portion of an IC package and/or a larger apparatus such as a mobile phone, etc.

As shown in FIG. 3, in some aspects, the apparatus 300 includes a die 310 coupled to a package substrate 320, an embedded scaffold stiffener 350, top external stiffener 360, a lid 365 and connectors 330. Note that the lid 365 and stiffener 360 may be separate, or a single monolithic piece, depending on lid construction desired. In some aspects, the embedded scaffold stiffener 350 includes a plurality of scaffold columns 355 and a plurality of scaffold layers 351. In the various aspects disclosed, the embedded scaffold stiffener 350 is part of the package substrate 320. In some aspects, the package substrate 320 may include a metallization structure 321 disposed in the package substrate 320. The metallization structure 321 may include a plurality of conductive layers 324 including metal layers and vias and a plurality of dielectric layers 322 disposed between the metal layers. The embedded scaffold stiffener 350 may be disposed on a perimeter of the metallization structure 321 (which may also be a perimeter of the package substrate 320) outside the metallization structure 321, as illustrated. Further, a top external stiffener 360 may be disposed on top of the embedded scaffold stiffener 350 and coupled to the embedded scaffold stiffener 350 by a bonding layer 362. The lid 365 is coupled to the top external stiffener 360 and in some aspects may be formed as an integrated (monolithic) structure with the top external stiffener. In some aspects the lid 365 may be coupled to the die 310 by a lid adhesive 366. It will be appreciated that the lid 365 may provide additional rigidity in combination with the top external stiffener 360 to prevent substrate warping. Further, the lid 365 may provide a thermal cooling path to the die 310 through the lid adhesive 366. In some aspects, the lid 365 in combination with the top external stiffener 360 may substantially enclose the die 310 and a top portion of the package substrate 320. In some aspects, the lid 365 in combination with the top external stiffener 360 may be configured to function as a Faraday cage for the die 310. For example, the lid 365 and the top external stiffener 360 may be electrically conductive and coupled to ground to provide for the increased EMI shielding and noise suppression.

In some aspects, the top external stiffener 360 and/or lid 365 may be electrically conductive. In some aspects, the top external stiffener 360 and/or lid 365 may be non-conductive. Likewise, the bonding layer 362 and/or lid adhesive 366 may be electrically conductive or non-conductive. It will be appreciated that the top external stiffener 360 and lid 365 provides for further stiffening of the package substrate 320.

FIG. 4 is a partial cross-sectional view of an apparatus 400, according to aspects of the disclosure. In some aspects, FIG. 4 is a simplified partial cross-sectional view of the apparatus 400, and certain details and components of the apparatus 400 may be simplified or omitted in FIG. 4, particularly details that are similar to the foregoing FIGS. 1A through 3. In some aspects, the apparatus 400 may be a portion of an IC package and/or a larger apparatus such as a mobile phone, etc.

FIG. 4 illustrates a detailed view of embedded scaffold stiffener 450 and top external stiffener 460 of apparatus 400, which is similar to apparatus 300 except that the top external stiffener may include a first portion 460a generally vertically aligned with the embedded scaffold stiffener 450 and a second portion 460b that extends over a routing area (e.g., the metallization structure) of a package substrate 420. In some aspects, the embedded scaffold stiffener 450 includes a plurality of scaffold columns 455 and a plurality of scaffold layers 451 (e.g., 451a, 451b . . . 451n). As discussed above, each of the other scaffold layers 451 includes a metal layer, a plurality of stubs coupled to the metal layer, vias and a dielectric layer 422 disposed over the metal layer, stubs and vias. To avoid redundancy and clutter in the drawings, each of these elements may not be individually identified and/or illustrated. In some aspects, the same dielectric layers 422 in the package substrate 420 are used in the embedded scaffold stiffener 450. In some aspects, the metallization structure may be formed at the same time as the embedded scaffold stiffener 450 from the same materials. It will be appreciated that the scaffold layers 451a to 451n of the embedded scaffold stiffener 450 can be designed for any number of layers and are sequentially coupled until a last scaffold layer 451n of the plurality of scaffold layers 451a to 451n is coupled to a base metal layer 456 adjacent to the last scaffold layer 451n. Further, as illustrated, in some aspects, the bonding layer 462 couples the top external stiffener 460 to the embedded scaffold stiffener 450 at the top scaffold layer 451a. In some aspects the bonding layer 462 may be an adhesive, such as an epoxy or solder. In some aspects the top external stiffener 460 may be a metal such as stainless steel. In some aspects, the top external stiffener 460 may be another substrate, such as an interposer, a PCB or the like.

It will be appreciated that in the various aspects disclosed the number of scaffold layers 451a to 451n are not limited to a particular number of layers. In some aspects, the base metal layer 456 may be coupled to the connectors 430 through openings in a second solder resist layer 427 to allow for coupling to external components and/or to a ground potential, as discussed herein.

In some aspects, at least a portion of a top metal layer of the top scaffold layer 451a may be exposed through an opening in a first solder resist layer 426 to allow for coupling to the top external stiffener 460 via bonding layer 462. In some aspects, the bonding layer 462 may be an adhesive. In some aspects, the bonding layer 462 may be conductive material, such as solder. In some aspects, the bonding layer 462 may comprise an adhesive portion 462b and a conductive portion 462a, which is in contact with the top scaffold layer 451a. In some aspects, the top external stiffener 460 (also referred to as a lid foot, in some aspects) is coupled to the bonding layer 462 in an area beyond (e.g., second portion 460b) the solder resist opening in first solder resist layer 426 to improve warpage performance, reduce the embedded scaffold stiffener 450 footprint size, and to reduce the negative impact in the area available for routing, which may be used under the second portion 460b of the top external stiffener 460. Further, it will be appreciated that in some aspects, as discussed above, solder can be used to connect the external top external stiffener 460 to the embedded scaffold stiffener 450. In some aspects, solder provides strong mechanical connection (e.g., using solder with melting point above a conventional BGA melting point used for connectors 430) and provides a robust/direct thermal path from the backside of the die, through a lid (not illustrated), the top external stiffener 460 and embedded scaffold stiffener 450 to an external heat sink (e.g., PCB, external component, dedicated heat sink, etc.).

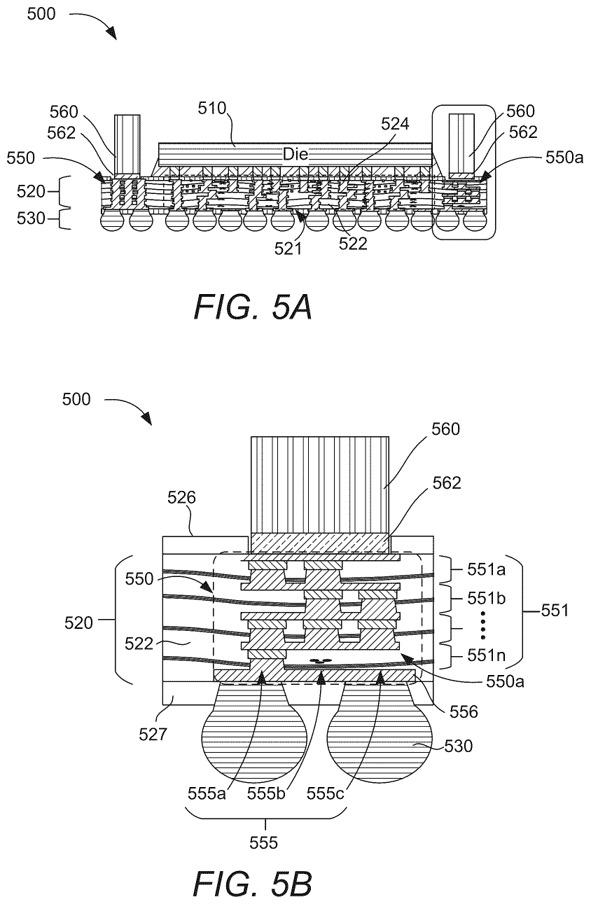

FIGS. 5A and 5B are partial cross-sectional views of an apparatus 500, according to aspects of the disclosure. In some aspects, FIGS. 5A and 5B are simplified partial cross-sectional views of the apparatus 500, and certain details and components of the apparatus 500 may be simplified or omitted in FIGS. 5A and 5B, particularly details that are similar to FIGS. 1A to 4. In some aspects, the apparatus 500 may be a portion of an IC package and/or a larger apparatus such as a mobile phone, etc.

As shown in FIG. 5A, in some aspects, the apparatus 500 includes a die 510 coupled to a package substrate 520, an embedded scaffold stiffener 550, top external stiffener 560 and connectors 530. In some aspects, the package substrate 520 may include a metallization structure 521 disposed in the package substrate 520. The metallization structure may include a plurality of conductive layers 524 including metal layers and vias and a plurality of dielectric layers 522. The embedded scaffold stiffener 550 may be disposed on a perimeter of the metallization structure 521 (which may also be a perimeter of the package substrate 520) outside the metallization structure 521, as illustrated. Further, a top external stiffener 560 may be disposed on top of the embedded scaffold stiffener 550 and coupled to the embedded scaffold stiffener 550 by a bonding layer 562. The top external stiffener 560 may be electrically conductive or non-conductive. Likewise, the bonding layer 562 may be electrically conductive or non-conductive. It will be appreciated that the top external stiffener 560 provides for further stiffening of the package substrate 520.

FIG. 5B illustrates a more detailed view of embedded scaffold stiffener 550 and top external stiffener 560. To avoid redundancy and clutter in the drawings, each of these elements may not be individually identified and/or illustrated. As discussed above, generally each of the other scaffold layers includes a metal layer, a plurality of stubs and vias coupled to the metal layer and a dielectric layer disposed over the metal layer, stubs and vias. In some aspects, the embedded scaffold stiffener 550 may include a routing portion 550a which includes a plurality of scaffold layers 551a to 551n, This allows for gaps in the scaffold columns 555 or partial scaffold columns, where each scaffold column 555 (e.g., 555a, 555b and 555c) includes the metal layers, stubs and vias that are vertically aligned. For example, as illustrated, the embedded scaffold stiffener 550 has a routing portion 550a where at least one of the plurality of scaffold layers 551 (e.g., 551a, 551b to 551n) has at least one less stub and via than the plurality of stubs and vias of the plurality of scaffold layers 551 outside the routing portion 550a. For example, in scaffold layer 551a the stub and via in scaffold column 555c is removed. In scaffold layer 551b, the stub and via in scaffold column 555a is removed. In scaffold layer 551n, the stubs and vias in scaffold columns 555b and 555c are removed. It will be appreciated that these removed stubs and vias in combination with other removed stubs in vias in adjacent columns of the embedded scaffold stiffener 550 can provide paths for escape routing from the metallization structure 521 through the embedded scaffold stiffener 550, as will be discussed further below.

It will be appreciated that the scaffold layers 551a to 551n of the embedded scaffold stiffener 550 can be designed for any number of layers and are sequentially coupled until a last scaffold layer 551n of the plurality of scaffold layers 551a to 551n is coupled to a base metal layer 556 adjacent to the last scaffold layer 551n. Further, as illustrated, in some aspects, the bonding layer 562 couples the top external stiffener 560 to the embedded scaffold stiffener 550 at the top scaffold layer 551a. In some aspects the bonding layer 562 may be an adhesive, such as an epoxy or solder. In some aspects the top external stiffener 560 may be a metal such as stainless steel. In some aspects, the top external stiffener 560 may be another substrate, such as an interposer, a PCB or the like.

It will be appreciated that in the various aspects disclosed the number of scaffold layers 551a to 551n are not limited to a particular number of layers. In some aspects, at least a portion of a top metal layer of the top scaffold layer 551a may be exposed through an opening in a first solder resist layer 526 to allow for coupling to the top external stiffener 560 via bonding layer 562. In some aspects, the base metal layer 556 may be coupled to the connectors 530 through openings in a second solder resist layer 527 to allow for coupling to external components and/or to a ground potential, as discussed herein.

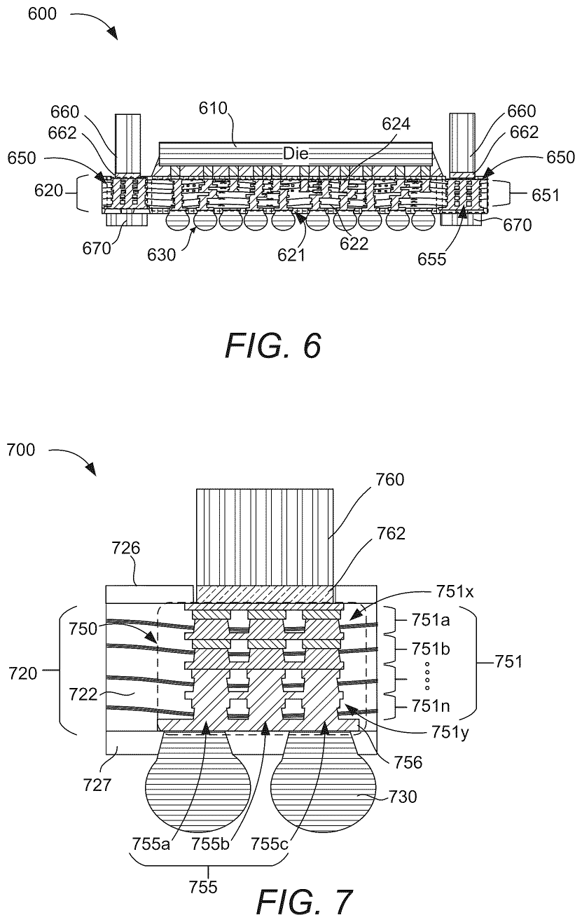

FIG. 6 is a partial cross-sectional view of an apparatus 600, according to aspects of the disclosure. In some aspects, FIG. 6 is a simplified cross-sectional view of the apparatus 600, and certain details and components of the apparatus 600 may be simplified or omitted in FIG. 6, particularly details that are similar to FIGS. 1A to 5B. In some aspects, the apparatus 600 may be a portion of an IC package and/or a larger apparatus such as a mobile phone, etc.

As shown in FIG. 6, in some aspects, the apparatus 600 includes a die 610 coupled to a package substrate 620, an embedded scaffold stiffener 650, top external stiffener 660, a bottom external stiffener 670 and connectors 630. In some aspects, the embedded scaffold stiffener 650 includes a plurality of scaffold columns 655 and a plurality of scaffold layers 651. In some aspects, the package substrate 620 may include a metallization structure 621 disposed in the package substrate 620. The metallization structure 621 may include a plurality of conductive layers 624 including metal layers and vias and a plurality of dielectric layers 622. The embedded scaffold stiffener 650 may be disposed on perimeter of the metallization structure 621 (which may also be a perimeter of the package substrate 620) outside the metallization structure 621, as illustrated. Further, a top external stiffener 660 may be disposed on top of the embedded scaffold stiffener 650 and coupled to the embedded scaffold stiffener 650 by a bonding layer 662. The top external stiffener 660 may be electrically conductive or non-conductive. Additionally, the bonding layer 662 may be electrically conductive or non-conductive. It will be appreciated that the top external stiffener 660 provides for further stiffening of the package substrate 620. Likewise, the bottom external stiffener 670 disposed on the backside of the package substrate 620 provides even further stiffening/prevention of warpage of the package substrate 620. In some aspects, the bottom external stiffener 670 may be used without the top external stiffener 660. In some aspects, the bottom external stiffener 670 may extend to cover substantially the same perimeter area as the embedded scaffold stiffener 650. In some aspects, the bottom external stiffener 670 may only cover a portion of the embedded scaffold stiffener 650 to further stiffen areas where additional support is desired, such as routing portions where there is reduced scaffold column strength, portions without a top external stiffener 660 and/or areas where stress may be concentrated in the package substrate 620. It will be appreciated that the bottom external stiffener 670 is thinner, i.e., has a smaller height, than the height of the connectors 630 (e.g., the BGA ball standoff height, the socket pin height for LGA or package pin height for PGA) to prevent interference with connecting to external components. In some aspects, the bottom external stiffener 670 may be electrically conductive or non-conductive. In some aspects, the bottom external stiffener 670 may be formed from a metal such as stainless steel. In some aspects, the bottom external stiffener 670 can be coupled to the embedded scaffold stiffener 650 through multiple openings or can be coupled through one large opening in solder resist. In some aspects, a polymer or solder material may be used to couple the bottom external stiffener 670 to the embedded scaffold stiffener 650.

FIG. 7 is a partial cross-sectional view of an apparatus 700, according to aspects of the disclosure. In some aspects, FIG. 7 is a simplified cross-sectional view of the apparatus 700, and certain details and components of the apparatus 700 may be simplified or omitted in FIG. 7, particularly details that are similar to FIGS. 1A to 6. In some aspects, the apparatus 700 may be a portion of an IC package and/or a larger apparatus such as a mobile phone, etc.

FIG. 7 illustrates a detailed view of embedded scaffold stiffener 750 and top external stiffener 760 of apparatus 700. To avoid redundancy and clutter in the drawings, each of the previously introduced elements are not individually identified or illustrated. In some aspects, the same dielectric layers in the package substrate 720 are used in the embedded scaffold stiffener 750. In some aspects, the embedded scaffold stiffener 750 includes a plurality of scaffold columns 755 and a plurality of scaffold layers 751. It will be appreciated that the metallization structure (not illustrated) is formed at the same time as the embedded scaffold stiffener 750 from the same materials. As discussed above, generally each of the plurality of scaffold layers 751 includes a metal layer, a plurality of stubs coupled to the metal layer and a dielectric layer disposed over the metal layer and stubs and vias to couple the stubs to adjacent metal layers through the dielectric layers 722. In some aspects, the embedded scaffold stiffener 750 may include a plurality of scaffold layers 751 (e.g., 751a, 751b . . . 751n), where a first subset 751x of the plurality of scaffold layers 751 comprises a first metal and a second subset 751y of the plurality of scaffold layers comprises a second metal. For example, the first metal may be copper and the second metal may be molybdenum. However, it will be appreciated that the various aspects disclosed and claimed are not limited to these examples and any highly conductive metal, alloys and combinations thereof may be used. It will be appreciated that having two metals with different properties may improve the coefficient of thermal expansion (CTE) in the package substrate 720 and apparatus 700, which will improve the reduction of warpage over a wider range of temperatures. As illustrated, each scaffold column (755a, 755b and 755c) includes the metal layers, stubs and vias that are vertically aligned and accordingly, each scaffold column (755a, 755b and 755c) will be formed from both the first metal and the second metal. Additionally, the various aspects are not limited to the illustrated configurations and alternative configurations can include different metal layers combinations (e.g. Cu, moly, Cu), so that the moly is in the center of two Cu layers. Further, the various aspects can include more than two different metals.

It will be appreciated that the scaffold layers 751a to 751n of the embedded scaffold stiffener 750 can be designed for any number of layers and are sequentially coupled until a last scaffold layer 751n of the plurality of scaffold layers 751a to 751n is coupled to a base metal layer 756 adjacent to the last scaffold layer 751n. In some aspects the base metal layer 756 may comprise the second metal. In some aspects the base metal layer 756 may comprise the first metal. Further, as illustrated, in some aspects, the bonding layer 762 couples the top external stiffener 760 to the embedded scaffold stiffener 750 at the top scaffold layer 751a through an opening in solder resist layer 726. In some aspects the bonding layer 762 may be an adhesive, such as an epoxy or solder. In some aspects the top external stiffener 760 may be a metal such as stainless steel. In some aspects, the top external stiffener 760 may be another substrate, such as an interposer, a PCB or the like. In some aspects, the base metal layer 756 may be coupled to the connectors 730 through openings in a second solder resist layer 727 to allow for coupling to external components and/or to a ground potential, as discussed herein.

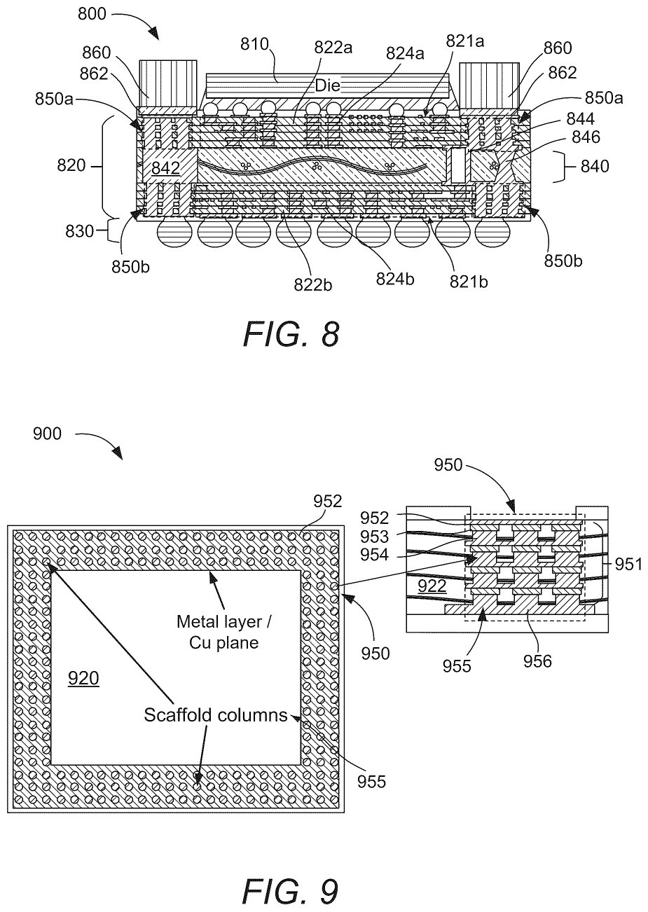

FIG. 8 is a partial cross-sectional view of an apparatus 800, according to aspects of the disclosure. In some aspects, FIG. 8 is a simplified partial cross-sectional view of the apparatus 800, and certain details and components of the apparatus 800 may be simplified or omitted in FIG. 8, particularly details that are similar to FIGS. 1A to 7. In some aspects, the apparatus 800 may be a portion of an IC package and/or a larger apparatus such as a mobile phone, etc.

As shown in FIG. 8, in some aspects, the apparatus 800 includes a die 810 coupled to a package substrate 820, embedded scaffold stiffeners 850a and 850b, top external stiffener 860, a substrate core 840 and connectors 830. In some aspects, the embedded scaffold stiffeners 850a and 850b may be part of the package substrate 820. In some aspects, the package substrate 820 may include metallization structures 821a and 821b disposed in the package substrate 820. The metallization structures 821a and 821b may include a plurality of conductive layers 824a and 824b including metal layers and vias and a plurality of dielectric layers 822a and 822b. The embedded scaffold stiffeners 850a and 850b may be disposed on a perimeter of the package substrate 820 outside the metallization structures 821a and 821b, as illustrated. Further, a top external stiffener 860 may be disposed on top of the embedded scaffold stiffener 850a and coupled to the embedded scaffold stiffener 850a by a bonding layer 862. The top external stiffener 860 may be electrically conductive or non-conductive. Additionally, the bonding layer 862 may be electrically conductive or non-conductive. In some aspects, the embedded scaffold stiffeners include a top embedded scaffold stiffener 850a disposed on a top side of the substrate core 840 and a bottom embedded scaffold stiffener 850b disposed on a bottom side of the substrate core 840. In some aspects, the substrate core is a glass core or a fiberglass-reinforced core material. In some aspects, a scaffold core support, which may include a plurality of scaffold core supports (e.g., 842, 844, 846) is configured to couple (thermally and/or mechanically) the top embedded scaffold stiffener 850a and the bottom embedded scaffold stiffener 850b. It will be appreciated that in some aspects providing both thermal and mechanical coupling a thermal conduction path is provided through package substrate 820 including substrate core 840, along with transmission of any load/stress which increase the package substrate stiffness and reduces warpage. In some aspects the scaffold core support may include at least one of an embedded bar 842, a plated through hole (PTH) 844 (which can be plugged, plugged and Cu capped, or Cu filled), a double-sided laser drilled (DSLD) via 846 or combinations thereof. In some aspects the scaffold core support is formed from a plurality of the embedded bar 842, the plated through hole (PTH) 844 or the double-sided laser drilled (DSLD) via 846 disposed around the perimeter of the package substrate 820.

FIG. 9 is a partial plan view and partial cross-sectional view of an apparatus 900, according to aspects of the disclosure. In some aspects, FIG. 9 is a simplified cross-sectional view of the apparatus 900, and certain details and components of the apparatus 900 may be simplified or omitted in FIG. 9, particularly details that are similar to the foregoing FIGS. 1A through 8. In some aspects, the apparatus 900 may be a portion of an IC package and/or a larger apparatus such as a mobile phone, etc.

FIG. 9 illustrates a partial plan view of embedded scaffold stiffener 950 of a package substrate 920 of apparatus 900, which may be similar to the other apparatuses discussed herein. In some aspects, the embedded scaffold stiffener 950 includes a plurality of scaffold layers 951 (which as discussed above may be any number from 1-n). Also, as discussed above, each of the plurality of scaffold layers includes a metal layer 952, a plurality of stubs 953 coupled to the metal layer 952 and a dielectric layer 922 disposed over the metal layer and plurality of stubs 953. A plurality of vias 954 are coupled to the plurality of stubs 953 and to adjacent metal layers 952 of the embedded scaffold stiffener 950. The vertically aligned stubs 953 and vias 954 in each layer form a plurality of scaffold columns 955. To avoid redundancy and clutter in the drawings, each of these elements may not be individually identified and/or illustrated. It will be appreciated that the scaffold layers 951 of the embedded scaffold stiffener 950 can be designed for any number of layers and are sequentially coupled until a last scaffold layer of the plurality of scaffold layers 951 is coupled to a base metal layer 956 adjacent to the last scaffold layer. Further, as illustrated, in some aspects, the embedded scaffold stiffener 950 is configured as a ring enclosing all sides of the perimeter of the package substrate 920. In some aspects, the scaffold columns 955 can be configured in a grid pattern within the ring, as illustrated. However, it will be appreciated that the various aspects disclosed and claimed are not limited to the illustrated examples provided herein. For example, in some aspects the embedded scaffold stiffener 950 may have portions with different widths and different numbers of scaffold columns 955. Further, the scaffold columns 955 may have different patterns (e.g., circular patterns, diagonal patterns, random patterns, etc.), different dimensions and/or shapes. Accordingly, in some aspects, the stubs 953 and vias 954 forming the scaffold columns 955 may have different dimensions (e.g., differing diameters, length, width, and/or height) and/or different shapes (e.g., circular, oval, rectangular, square, tapered, etc.). Additionally, the various scaffold layers may comprise a common material or may comprise different materials. Additional non-limiting examples will be provided in the following paragraphs.

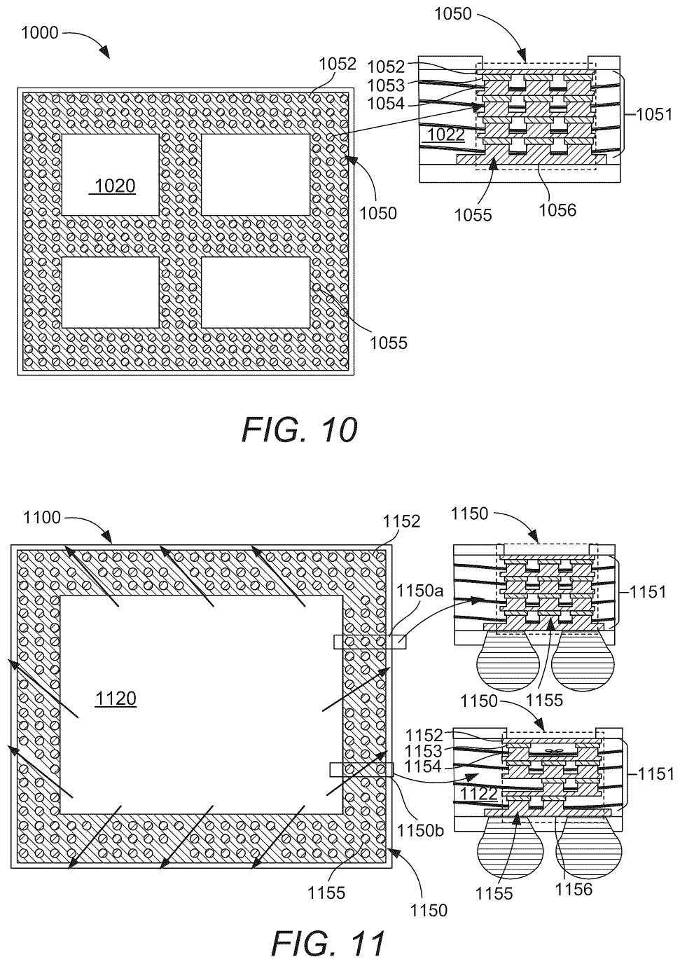

FIG. 10 is a partial plan view and partial cross-sectional view of an apparatus 1000, according to aspects of the disclosure. In some aspects, FIG. 10 is a simplified cross-sectional view of the apparatus 1000, and certain details and components of the apparatus 1000 may be simplified or omitted in FIG. 10, particularly details that are similar to the foregoing FIGS. 1A through 9. In some aspects, the apparatus 1000 may be a portion of an IC package and/or a larger apparatus such as a mobile phone, etc.

FIG. 10 illustrates a partial plan view of embedded scaffold stiffener 1050 of a package substrate 1020 of apparatus 1000, which may be similar to the other apparatuses discussed herein. In some aspects, the embedded scaffold stiffener 1050 includes a plurality of scaffold layers 1051. Also, as discussed above, each of the plurality of scaffold layers 1051 includes a metal layer 1052, a plurality of stubs 1053 coupled to the metal layer 1052 and a dielectric layer 1022 disposed over the metal layer and plurality of stubs 1053. A plurality of vias 1054 is coupled to the plurality of stubs 1053 and to adjacent metal layers 1052 of the embedded scaffold stiffener 1050. The vertically aligned stubs 1053 and vias 1054 in each layer form a plurality of scaffold columns 1055. To avoid redundancy and clutter in the drawings, each of these elements is not individually identified. In some aspects, the same dielectric layers 1022 in the package substrate 1020 are used in the embedded scaffold stiffener 1050. It will be appreciated that the scaffold layers 1051 of the embedded scaffold stiffener 1050 can be designed for any number of layers and are sequentially coupled until a last scaffold layer of the plurality of scaffold layers 1051 is coupled to a base metal layer 1056 adjacent to the last scaffold layer. Further, as illustrated, in some aspects, the embedded scaffold stiffener 1050 is configured as a ring enclosing all sides of the perimeter of the package substrate 1020 and further includes at least one internal channel disposed between opposite sides of the ring (in the illustrated example two channels are illustrated, with each channel being orthogonal to the other forming a cross within the ring. In some aspects, the scaffold columns 1055 can be configured in a grid pattern, as illustrated. However, it will be appreciated that the various aspects disclosed and claimed are not limited to the illustrated examples provided herein.

FIG. 11 is a partial plan view and partial cross-sectional views of an apparatus 1100, according to aspects of the disclosure. In some aspects, FIG. 11 is a simplified cross-sectional view of the apparatus 1100, and certain details and components of the apparatus 1100 may be simplified or omitted in FIG. 11, particularly details that are similar to the foregoing FIGS. 1A through 10. In some aspects, the apparatus 1100 may be a portion of an IC package and/or a larger apparatus such as a mobile phone, etc.

FIG. 11 illustrates a partial plan view of embedded scaffold stiffener 1150 of a package substrate 1120 of apparatus 1100, which may be similar to the other apparatuses discussed herein. In some aspects, the embedded scaffold stiffener 1150 includes a plurality of scaffold layers 1151. Also, as discussed above, each of the plurality of scaffold layers 1151 includes a metal layer 1152, a plurality of stubs 1153 coupled to the metal layer 1152 and a dielectric layer 1122 disposed over the metal layer 1152 and plurality of stubs 1153. A plurality of vias 1154 are coupled to the plurality of stubs 1153 and to adjacent metal layers 1152 of the embedded scaffold stiffener 1150. The vertically aligned stubs 1153 and vias 1154 in each layer form a plurality of scaffold columns 1155. To avoid redundancy and clutter in the drawings, each of these elements may not be individually identified and/or illustrated. It will be appreciated that the scaffold layers 1151 of the embedded scaffold stiffener 1150 can be designed for any number of layers and are sequentially coupled until a last scaffold layer of the plurality of scaffold layers 1151 is coupled to a base metal layer 1156 adjacent to the last scaffold layer. Further, as illustrated, in some aspects, the embedded scaffold stiffener 1150 is configured as a ring enclosing all sides of the perimeter of the package substrate 1120 with at least one routing portion 1150b having a reduced number of stubs and vias compared to portions 1150a without any opening in the ring. It will be appreciated that the openings formed by the missing stubs and vias in the routing portion may be staggered on various scaffold layers 1151 and in various scaffold columns 1155 depending on the various design parameters. It will be appreciated that having one or more routing portions 1150b allows for increased routing flexibility while still maintaining an increased stiffness which reduces warpage of the package substrate 1120. In some aspects, the scaffold columns 1155 can be configured in a grid pattern within the ring and the routing portions 1150b can be configured to allow for routing paths at angles to the grid pattern of the scaffold columns 1155, as illustrated. However, it will be appreciated that the various aspects disclosed and claimed are not limited to the illustrated examples provided herein.

In order to fully illustrate the various aspects of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

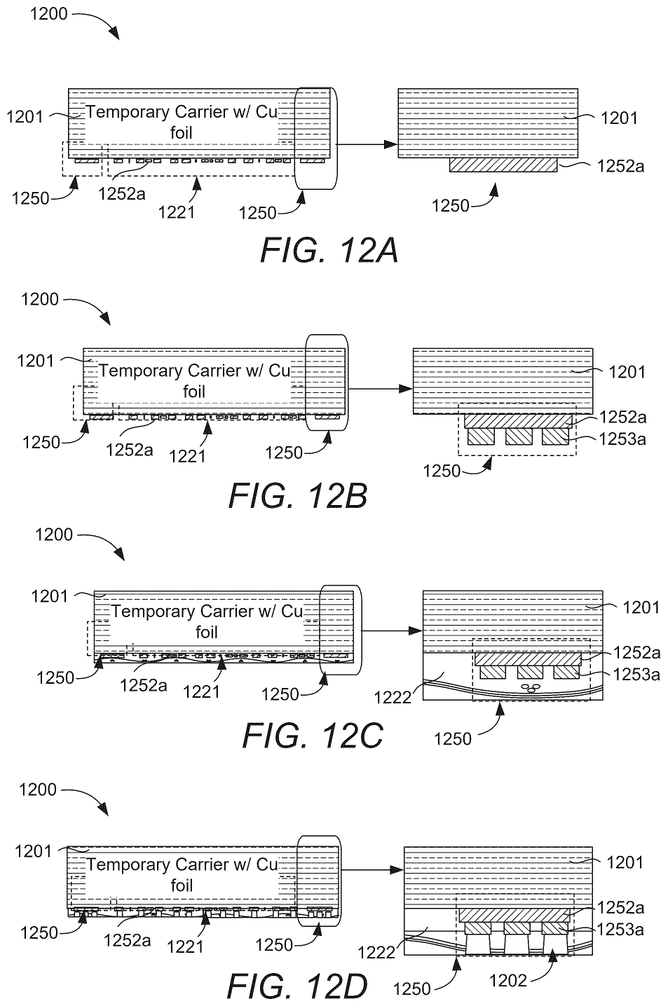

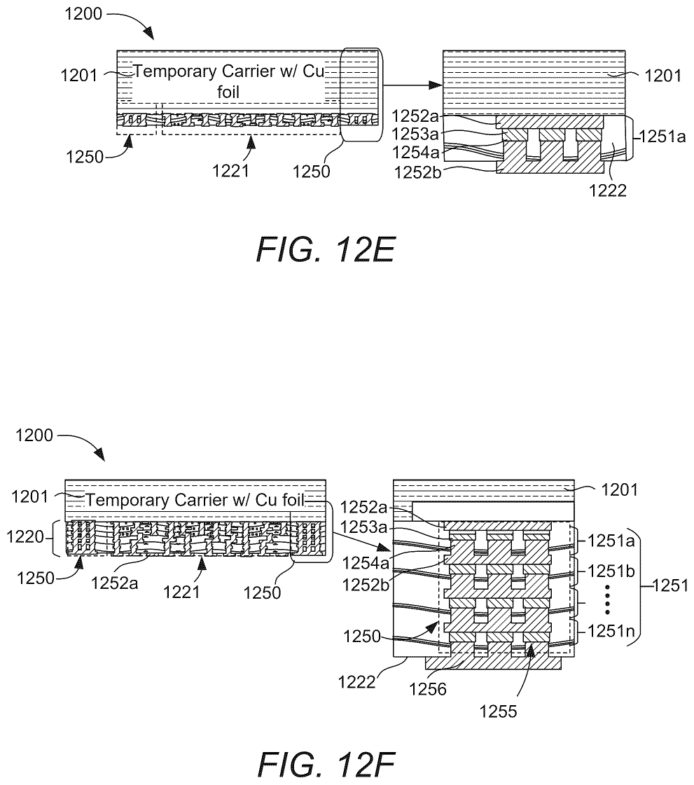

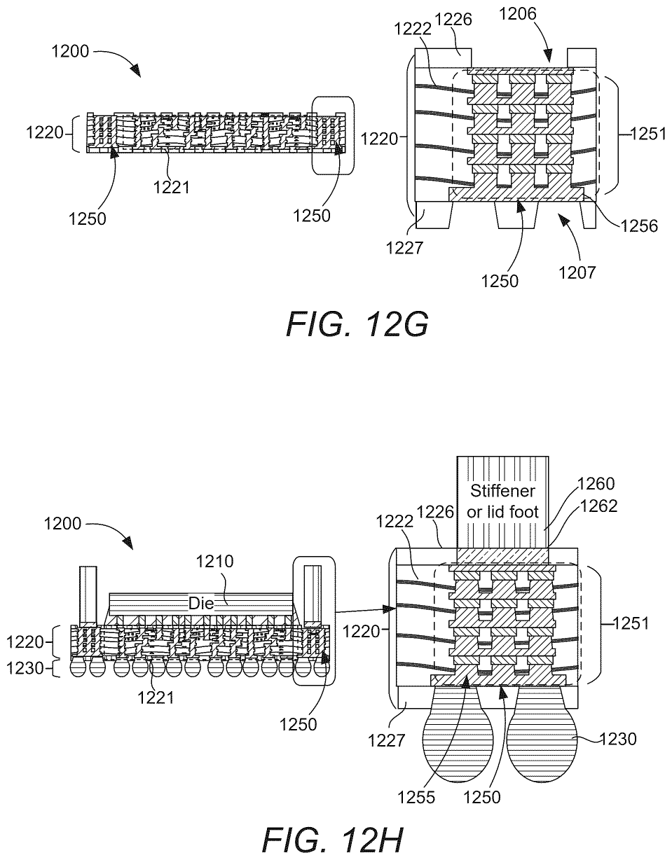

FIGS. 12A-12H illustrate structures at various stages of manufacturing/fabricating an apparatus 1200, such as the example apparatuses 100 to 1100, discussed above, as non-limiting examples, according to aspects of the disclosure. Many of the elements illustrated in FIGS. 12A-12H are the same or similar to those of discussed above and illustrated in the accompanying drawings, and therefore detailed description thereof may be omitted.

As shown in FIG. 12A, the fabrication process for apparatus 1200 may begin with providing a temporary carrier 1201 having a copper foil applied to a first surface. A first dry film resist (DFR) can be deposited, exposed, developed, and electroplated to pattern and form a first metal layer 1252a (e.g., M1 Cu layer). In some aspects, the first metal layer 1252a forms a portion of an embedded scaffold stiffener 1250 and a metallization structure 1221.

In FIG. 12B, the fabrication process for apparatus 1200 may continue with the temporary carrier 1201 having the first metal layer 1252a attached. In some aspects, the fabrication process may further continue with the first DFR being stripped and a second DFR being deposited and patterned then an electroplating process can be used to form first stubs 1253a in an M1.5 layer. In some aspects, the first metal layer 1252a and first stubs 1253a form a portion of the embedded scaffold stiffener 1250.

In FIG. 12C, the fabrication process for apparatus 1200 may continue with the temporary carrier 1201 having the first metal layer 1252a and the first stubs 1253a attached. In some aspects, the fabrication process may further continue with a dielectric 1222 being deposited/laminated over the first metal layer 1252a and the first stubs 1253a. In some aspects, the first metal layer 1252a, first stubs 1253a and dielectric 1222 form a portion of the embedded scaffold stiffener 1250 and metallization structure 1221. In some aspects, the dielectric 1222 may comprise fiberglass impregnated with resin (prepreg), Ajinomoto build-up film (ABF), other build-up films or any similar material.

In FIG. 12D, the fabrication process for apparatus 1200 may continue with the temporary carrier 1201 having the first metal layer 1252a, first stubs 1253a and dielectric 1222 attached. In some aspects, the fabrication process may further continue with openings 1202 in the dielectric 1222 being formed to allow access to the first stubs 1253a. In some aspects, the openings 1202 may be formed by laser drilling through dielectric 1222.

In FIG. 12E, the fabrication process for apparatus 1200 may continue with the temporary carrier 1201 having the first metal layer 1252a, first stubs 1253a and dielectric 1222 attached. In some aspects, the fabrication process may further continue with openings in the dielectric 1222 being filled with a conductive material (e.g., Cu) forming first vias 1254a coupled to the first stubs 1253a. Further a second metal layer 1252b is deposited and patterned. In some aspects, the first metal layer 1252a, the first stubs 1253a, the first vias 1254a, the second metal layer 1252b and dielectric 1222 may form a portion of the embedded scaffold stiffener 1250 and the metallization structure 1221.

In FIG. 12F, the fabrication process for apparatus 1200 may continue with the temporary carrier 1201 having the first metal layer 1252a, the first stubs 1253a, the first vias 1254a, the second metal layer 1252b and dielectric 1222 attached. In some aspects, the fabrication process may further continue with the processes of 12B thru 12E being repeated forming a plurality of scaffold layers 1251 (e.g., 1251a, 1251b, to 1251n) until all metal layers are formed and patterned including the base metal layer 1256 in both the embedded scaffold stiffener 1250 and the metallization structure 1221 of the package substrate 1220. Additionally, the embedded scaffold stiffener 1250 has a plurality of scaffold columns 1255 formed by the vertically aligned stubs and vias.

In FIG. 12G, the fabrication process for apparatus 1200 may continue with packaged substrate being removed from the temporary carrier 1201 (e.g., de-panel from temporary carrier). A first solder resist (SR) 1226 and second solder resist (SR) 1227 is deposited and processed to form openings 1206 and 1207, in desired portions of the first SR 1226 and second SR 1227, respectively. At this stage, the package substrate 1220 has first SR 1226 and second SR 1227, the plurality of scaffold layers 1251 and the plurality of scaffold columns 1255 of the embedded scaffold stiffener 1250 and the metallization structure 1221 formed.

In FIG. 12H, the fabrication process for apparatus 1200 may continue with a die 1210 being attached and electrically coupled to the metallization structure 1221 of the package substrate 1220. Connectors 1230 (e.g., solder balls) are attached to the metallization structure 1221 and the embedded scaffold stiffener 1250. The embedded scaffold stiffener 1250 includes the plurality of scaffold layers 1251 and the plurality of scaffold columns 1255. Optionally, a top external stiffener 1260 may be disposed on top of the embedded scaffold stiffener 1250 and coupled to the embedded scaffold stiffener 1250 by a bonding layer 1262.

It will be appreciated that additional processing can be performed using known techniques to form and/or attach additional structures (e.g., lid, PCB, additional dies, SMT components, etc.). Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

In some aspects, the various top external stiffeners (e.g., 260, 360) disclosed may have a height in the range of 1 to 3 millimeters. In some aspects, the height of the various vias (e.g., 154, 254, etc.) disclosed may be in the range 10 to 50 micrometers (um), and the diameter of the vias (e.g., 154, 254, etc.) and stubs (e.g., 153, 254, etc.) disclosed may be in the range 50 to 100 micrometers (um), In some aspects, the diameters of the vias and stubs may vary, e.g., a larger diameter may occur in one or more scaffold columns (e.g., center scaffold column, outer scaffold column, etc.). In some aspects, the number of scaffold columns (e.g., 155, 255, etc.) disclosed may be in the range of 2 to 5.

It will be appreciated that the various metal layers (e.g., 152, etc.) and other metal structures (e.g., vias (e.g., 154, etc.), stubs (e.g., 153, etc.)) may comprise any high conductive material, such as, copper (Cu), aluminum (Al), silver (Ag), gold (Au) titanium (Ti), nickel (Ni), molybdenum, alloys or combinations thereof. Further, it will be appreciated that the various the dielectric layers (e.g., 122, 222, etc.) may comprise fiberglass impregnated with resin (prepreg), Ajinomoto build-up film (ABF), photoimageable dielectric materials, or other build-up films or any similar material. Accordingly, it will be appreciated that the various aspects disclosed and claimed are not limited to the various example configurations and materials provided herein.

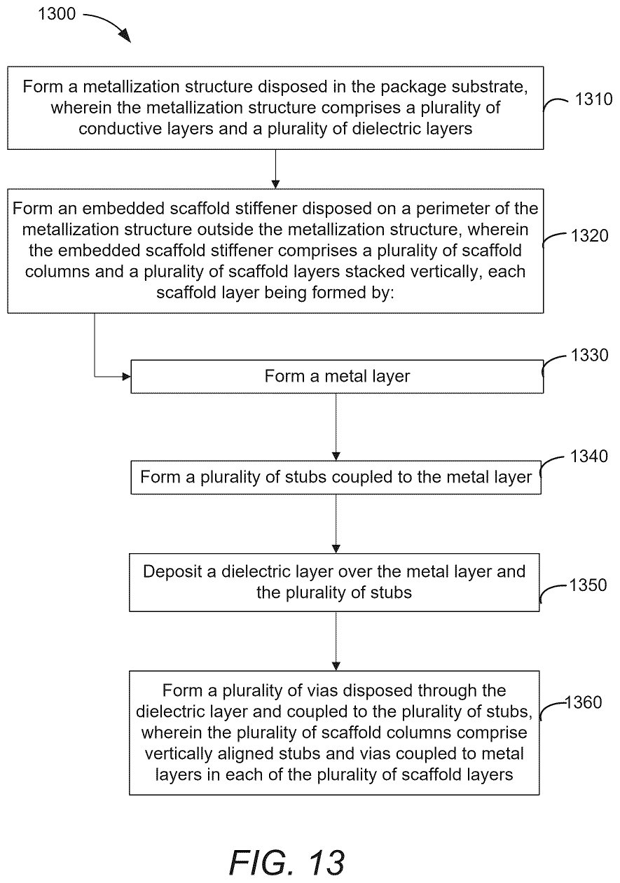

FIG. 13 illustrates a method 1300 for manufacturing/fabricating and apparatus with a substrate with an embedded scaffold stiffener (e.g., any of the example apparatuses 100 through 1200), according to aspects of the disclosure. In some aspects, FIGS. 12A-12H may depict the substrate at different stages of manufacturing according to the method 1300. It will be appreciated from the foregoing that there are various methods for fabricating devices including a substrate with an embedded scaffold stiffener as disclosed herein.

At operation 1310, the process includes forming a metallization structure disposed in the package substrate (e.g., 120, 220, 320, 420, 520, 620, 720, 820, 920, 1020, 1120, or 1220) wherein the metallization structure (e.g., metallization structure 121, 221, 321, etc.) comprises a plurality of conductive layers (e.g., conductive layers 124, 224, 324, etc.) and a plurality of dielectric layers (e.g., dielectric layers 122, 222, 322, etc.).

At operation 1320, the process includes forming an embedded scaffold stiffener (e.g., 150, 250, 350, 450, 550, 650, 750, 850a, 850b, 950, 1050, 1150, or 1250) disposed on a perimeter of the metallization structure (which may be a perimeter of the package substrate (e.g., package substrate 120, 220, 320, 420, 520, 620, 720, 820, 920, 1020, 1120, or 1220)) outside the metallization structure (e.g., metallization structure 121, 221, 321, etc.), wherein the embedded scaffold stiffener comprises a plurality of scaffold columns (e.g., scaffold columns 155, 255, 355, etc.) and a plurality of scaffold layers (e.g., scaffold layers 151, 251, 351, etc.) stacked vertically, each scaffold layer being formed by the following operations 1330 to 1360. In various aspects, it will be appreciated that the formation of metallization structure, operation 1310, and the embedded scaffold stiffener, operation 1320, is performed in parallel as each layer is fabricated.

At operation 1330, the process includes forming a metal layer (e.g., metal layer 152).

At operation 1340, the process includes forming a plurality of stubs (e.g., stubs 153) coupled to the metal layer (e.g., metal layer 152).

At operation 1350, the process includes depositing a dielectric layer (e.g., dielectric layer 122) over the metal layer (e.g., metal layer 152) and the plurality of stubs (e.g., stubs 153).

At operation 1350, the process includes forming a plurality of vias (e.g., 154) disposed through the dielectric layer (e.g., dielectric layer 122) over the metal layer (e.g., 152) and the plurality of stubs (e.g., stubs 153).

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

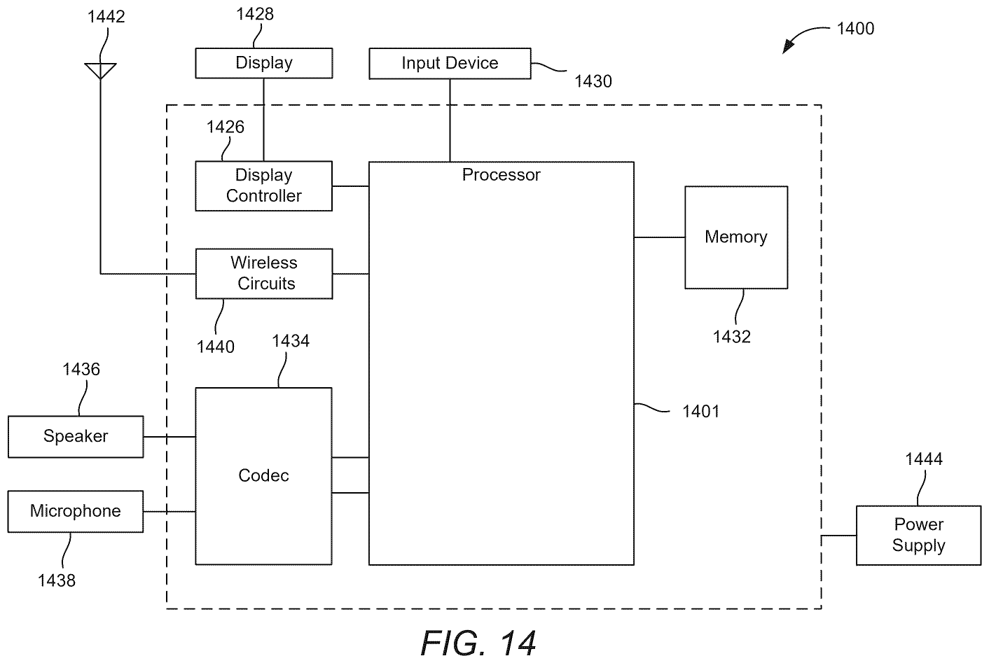

FIG. 14 illustrates a mobile device 1400, according to aspects of the disclosure. In some aspects, the mobile device 1400 may be implemented by including one or more IC devices including the hybrid substrate with embedded components as disclosed herein.

In some aspects, mobile device 1400 may be configured as a wireless communication device. As shown, mobile device 1400 includes processor 1401. Processor 1401 may be communicatively coupled to memory 1432 over a link, which may be a die-to-die or chip-to-chip link. Mobile device 1400 also includes display 1428 and display controller 1426, with display controller 1426 coupled to processor 1401 and to display 1428. The mobile device 1400 may include input device 1430 (e.g., physical, or virtual keyboard), power supply 1444 (e.g., battery), speaker 1436, microphone 1438, and wireless antenna 1442. In some aspects, the power supply 1444 may directly or indirectly provide the supply voltage for operating some or all of the components of the mobile device 1400.

In some aspects, FIG. 14 may include coder/decoder (CODEC) 1434 (e.g., an audio and/or voice CODEC) coupled to processor 1401; speaker 1436 and microphone 1438 coupled to CODEC 1434; and wireless circuits 1440 (which may include a modem, RF circuitry, filters, etc.) coupled to wireless antenna 1442 and to processor 1401.

In some aspects, one or more of processor 1401 (e.g., SoCs, application processor (AP), central processing unit (CPU), digital signal processor (DSP), etc.), display controller 1426, memory 1432, CODEC 1434, and wireless circuits 1440 (e.g., baseband interface) including IC devices that are packaged as IC packages and including substrates with an embedded scaffold stiffener according to the various aspects described in this disclosure.

It should be noted that although FIG. 14 depicts a mobile device 1400, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

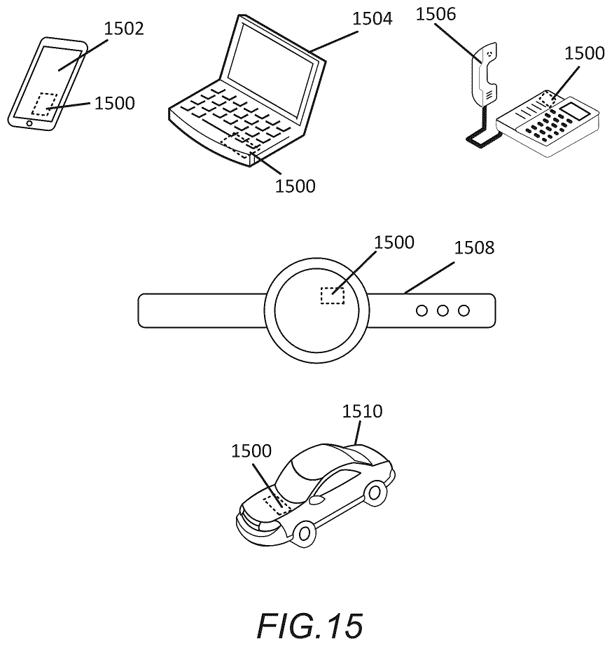

FIG. 15 illustrates various electronic devices that may be integrated with any of the aforementioned devices, semiconductor devices, integrated circuit (IC) packages, integrated circuit (IC) devices, electronic components, interposer packages, package-on-package (POP), System in Package (SiP), or System on Chip (SoC). For example, a mobile phone device 1502, a laptop computer device 1504, a fixed location terminal device 1506, a wearable device 1508, or automotive vehicle 1510 may include a semiconductor device 1500 (e.g., including embedded scaffold stiffeners) as described herein. The devices 1502, 1504, 1506 and 1508 and the vehicle 1510 illustrated in FIG. 15 are merely exemplary. Other apparatuses or devices may also feature the semiconductor device 1500 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 15 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1A-15 may be rearranged and/or combined into a single component, process, feature, or function or incorporated in several components, processes, or functions. Additional elements, components, processes, and/or functions may also be added without departing from the disclosure. In some implementations, FIGS. 1A-15 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus comprising: a metallization structure disposed in a package substrate, wherein the metallization structure comprises a plurality of conductive layers and a plurality of dielectric layers; and an embedded scaffold stiffener disposed on a perimeter of the metallization structure outside the metallization structure, wherein the embedded scaffold stiffener comprises a plurality of scaffold columns and a plurality of scaffold layers stacked vertically, each scaffold layer comprising: a metal layer; a plurality of stubs coupled to the metal layer; a dielectric layer disposed over the metal layer and the plurality of stubs; and a plurality of vias disposed through the dielectric layer and coupled to the plurality of stubs, wherein the plurality of scaffold columns comprise vertically aligned stubs and vias coupled to metal layers in each of the plurality of scaffold layers.

Clause 2. The apparatus of clause 1, wherein each of the plurality of vias are coupled to a next metal layer of a next scaffold layer of the plurality of scaffold layers or a base metal layer adjacent a last scaffold layer of the plurality of scaffold layers.

Clause 3. The apparatus of any of clauses 1 to 2, further comprising: a top external stiffener coupled to embedded scaffold stiffener through a bonding layer.

Clause 4. The apparatus of clause 3, wherein the bonding layer comprises an adhesive or solder.

Clause 5. The apparatus of clause 4, wherein the top external stiffener comprises a metal or another substrate.

Clause 6. The apparatus of any of clauses 3 to 5, further comprises: a lid coupled to the top external stiffener.

Clause 7. The apparatus of clause 6, wherein the top external stiffener comprises: a first portion vertically aligned with the embedded scaffold stiffener; and a second portion extending over the metallization structure of the package substrate.

Clause 8. The apparatus of clause 7, wherein the bonding layer extends at least partially under the second portion.

Clause 9. The apparatus of clause 8, wherein the bonding layer comprises: a conductive portion disposed between the embedded scaffold stiffener and the first portion of the top external stiffener; and an adhesive portion disposed at least partially under the second portion.

Clause 10. The apparatus of any of clauses 1 to 9, wherein embedded scaffold stiffener comprises a plurality of routing portions, wherein in each routing portion at least one of the plurality of scaffold layers has at least one less stub and via than the plurality of stubs and vias of the plurality of scaffold layers outside each routing portion.

Clause 11. The apparatus of any of clauses 1 to 10, further comprising: a bottom external stiffener disposed on a backside of the package substrate adjacent to the embedded scaffold stiffener.

Clause 12. The apparatus of any of clauses 1 to 11, wherein the package substrate further comprises: a substrate core.

Clause 13. The apparatus of clause 12, wherein the embedded scaffold stiffener further comprises: a top embedded scaffold stiffener disposed on a top side of the substrate core; a bottom embedded scaffold stiffener disposed on a bottom side of the substrate core; and a scaffold core support configured to couple the top embedded scaffold stiffener and the bottom embedded scaffold stiffener.

Clause 14. The apparatus of clause 13, wherein the scaffold core support is at least one of: an embedded bar; a plated through hole (PTH); a double-sided laser drilled (DSLD) via; or combinations thereof.

Clause 15. The apparatus of any of clauses 1 to 14, wherein: the embedded scaffold stiffener is a ring enclosing all sides of the perimeter of the metallization structure, the embedded scaffold stiffener comprises a ring enclosing all sides of the perimeter of the metallization structure and at least one internal channel disposed between opposite sides of the ring, the embedded scaffold stiffener comprises a ring enclosing all sides of the perimeter of the metallization structure with at least one routing portion having a reduced number of stubs and vias, or the embedded scaffold stiffener comprises a ring enclosing only a portion of the perimeter of the metallization structure.

Clause 16. The apparatus of any of clauses 1 to 15, further comprising: a die disposed on a top surface of the package substrate and electrically coupled to the metallization structure of the package substrate; and a plurality of connectors disposed on a bottom surface of the package substrate and electrically coupled to the embedded scaffold stiffener and the metallization structure of the package substrate.

Clause 17. The apparatus of any of clauses 1 to 16, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Clause 18. A method of manufacturing an apparatus, the method comprising: forming a metallization structure disposed in a package substrate, wherein the metallization structure comprises a plurality of conductive layers and a plurality of dielectric layers; and forming an embedded scaffold stiffener disposed on a perimeter of the metallization structure outside the metallization structure, wherein the embedded scaffold stiffener comprises a plurality of scaffold columns and a plurality of scaffold layers stacked vertically, each scaffold layer being formed by: forming a metal layer; forming a plurality of stubs coupled to the metal layer; depositing a dielectric layer over the metal layer and the plurality of stubs; and forming a plurality of vias disposed through the dielectric layer and coupled to the plurality of stubs, wherein the plurality of scaffold columns comprises vertically aligned stubs and vias coupled to metal layers in each of the plurality of scaffold layers.

Clause 19. The method of clause 18, further comprising: forming a top external stiffener coupled to embedded scaffold stiffener through a bonding layer.

Clause 20. The method of any of clauses 18 to 19, wherein: the embedded scaffold stiffener is a ring enclosing all sides of the perimeter of the package substrate, the embedded scaffold stiffener comprises a ring enclosing all sides of the perimeter of the package substrate and at least one internal channel disposed between opposite sides of the ring, the embedded scaffold stiffener comprises a ring enclosing all sides of the perimeter of the package substrate with at least one routing portion having a reduced number of stubs and vias, or the embedded scaffold stiffener comprises a ring enclosing only a portion of the perimeter of the package substrate.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus comprising:
a metallization structure disposed in a package substrate, wherein the metallization structure comprises a plurality of conductive layers and a plurality of dielectric layers; and
an embedded scaffold stiffener disposed on a perimeter of the metallization structure outside the metallization structure, wherein the embedded scaffold stiffener comprises a plurality of scaffold columns and a plurality of scaffold layers stacked vertically, each scaffold layer comprising:
a metal layer;
a plurality of stubs coupled to the metal layer;
a dielectric layer disposed over the metal layer and the plurality of stubs; and
a plurality of vias disposed through the dielectric layer and coupled to the plurality of stubs, wherein the plurality of scaffold columns comprise vertically aligned stubs and vias coupled to metal layers in each of the plurality of scaffold layers.

2. The apparatus of claim 1, wherein each of the plurality of vias are coupled to a next metal layer of a next scaffold layer of the plurality of scaffold layers or a base metal layer adjacent a last scaffold layer of the plurality of scaffold layers.

3. The apparatus of claim 1, further comprising:
a top external stiffener coupled to embedded scaffold stiffener through a bonding layer.

4. The apparatus of claim 3, wherein the bonding layer comprises an adhesive or solder.

5. The apparatus of claim 4, wherein the top external stiffener comprises a metal or another substrate.

6. The apparatus of claim 3, further comprises:
a lid coupled to the top external stiffener.

7. The apparatus of claim 6, wherein the top external stiffener comprises:
a first portion vertically aligned with the embedded scaffold stiffener; and
a second portion extending over the metallization structure of the package substrate.

8. The apparatus of claim 7, wherein the bonding layer extends at least partially under the second portion.

9. The apparatus of claim 8, wherein the bonding layer comprises:
a conductive portion disposed between the embedded scaffold stiffener and the first portion of the top external stiffener; and
an adhesive portion disposed at least partially under the second portion.

10. The apparatus of claim 1, wherein the embedded scaffold stiffener comprises a plurality of routing portions, wherein in each routing portion at least one of the plurality of scaffold layers has at least one less stub and via than the plurality of stubs and vias of the plurality of scaffold layers outside each routing portion.

11. The apparatus of claim 1, further comprising:
a bottom external stiffener disposed on a backside of the package substrate adjacent to the embedded scaffold stiffener.

12. The apparatus of claim 1, wherein the package substrate further comprises:
a substrate core.

13. The apparatus of claim 12, wherein the embedded scaffold stiffener further comprises:
a top embedded scaffold stiffener disposed on a top side of the substrate core;
a bottom embedded scaffold stiffener disposed on a bottom side of the substrate core; and
a scaffold core support configured to couple the top embedded scaffold stiffener and the bottom embedded scaffold stiffener.

14. The apparatus of claim 13, wherein the scaffold core support is at least one of:
an embedded bar;
a plated through hole (PTH);
a double-sided laser drilled (DSLD) via; or
combinations thereof.

15. The apparatus of claim 1, wherein:
the embedded scaffold stiffener comprises a ring enclosing all sides of the perimeter of the metallization structure,
the embedded scaffold stiffener comprises a ring enclosing all sides of the perimeter of the metallization structure and at least one internal channel disposed between opposite sides of the ring,
the embedded scaffold stiffener comprises a ring enclosing all sides of the perimeter of the metallization structure with at least one routing portion having a reduced number of stubs and vias, or
the embedded scaffold stiffener comprises a ring enclosing only a portion of the perimeter of the metallization structure.

16. The apparatus of claim 1, further comprising:
a die disposed on a top surface of the package substrate and electrically coupled to the metallization structure of the package substrate; and
a plurality of connectors disposed on a bottom surface of the package substrate and electrically coupled to the embedded scaffold stiffener and the metallization structure of the package substrate.

17. The apparatus of claim 1, wherein the apparatus comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a device in an automotive vehicle, an internet of things (IoT) device, or a server.

18. A method of manufacturing an apparatus, the method comprising:
forming a metallization structure disposed in a package substrate, wherein the metallization structure comprises a plurality of conductive layers and a plurality of dielectric layers; and
forming an embedded scaffold stiffener disposed on a perimeter of the metallization structure outside the metallization structure, wherein the embedded scaffold stiffener comprises a plurality of scaffold columns and a plurality of scaffold layers stacked vertically, each scaffold layer being formed by:
forming a metal layer;
forming a plurality of stubs coupled to the metal layer;
depositing a dielectric layer over the metal layer and the plurality of stubs; and
forming a plurality of vias disposed through the dielectric layer and coupled to the plurality of stubs, wherein the plurality of scaffold columns comprises vertically aligned stubs and vias coupled to metal layers in each of the plurality of scaffold layers.

19. The method of claim 18, further comprising:
forming a top external stiffener coupled to embedded scaffold stiffener through a bonding layer.

20. The method of claim 18, wherein:
the embedded scaffold stiffener comprises a ring enclosing all sides of the perimeter of the package substrate,
the embedded scaffold stiffener comprises a ring enclosing all sides of the perimeter of the package substrate and at least one internal channel disposed between opposite sides of the ring,
the embedded scaffold stiffener comprises a ring enclosing all sides of the perimeter of the package substrate with at least one routing portion having a reduced number of stubs and vias, or
the embedded scaffold stiffener comprises a ring enclosing only a portion of the perimeter of the package substrate.
